(19) United States
(12) Patent Application Publication
(10) Pub. No.: US 2023/0413534 A1
(43) Pub. Date: Dec. 21, 2023

(54) SEMICONDUCTOR DEVICE AND METHOD OF FORMING THE SAME

(71) Applicant: MICRON TECHNOLOGY, INC., Boise, ID (US)

(72) Inventors: Kunihiro Tsubomi, Higashihiroshima (JP); Akira Kono, Higashihiroshima (JP); Akinori Onishi, Higashihiroshima (JP)

(73) Assignee: MICRON TECHNOLOGY, INC., Boise, ID (US)

(21) Appl. No.: 17/841,509

(22) Filed: Jun. 15, 2022

(51) Int. Cl. H01L 27/108

(52) U.S. Cl. CPC H01L 27/10885; H01L 27/10814; H01L 27/10823

(57) ABSTRACT

An apparatus includes a plurality of bit-line structures elongating in parallel in a first direction, each of the plurality of bit-line structures having a conductive portion and an insulating portion on the conductive portion; wherein the insulating portion of each of the plurality of bit-line structures includes taper-shaped segments and less taper-shaped segments, which appear alternately along the first direction.

### BACKGROUND

In dynamic random access memory (hereinafter referred to as DRAM), the wiring pitch dimension is being reduced to increase the degree of integration. For this reason, the vertical dimension of structures is becoming greater relative to the horizontal dimension. For example, when structures that are long in the vertical direction are formed, stress occurs more readily in the horizontal direction, and in some cases, the upper portion of the structures where stress is readily concentrated, for example, is tapered to reduce the width dimension of the upper portion between adjacent structures. Thereafter, if an insulating material, for example, is embedded between the structures, the space between the structures may not be filled completely, and voids may be formed in some cases. If a conductive material, for example, is formed in a still later step, the conductive material may be formed in the voids and cause, for example, a short circuit between wiring to occur in some cases.

### BRIEF DESCRIPTION OF THE DRAWINGS

FIG. 1 is a plan view illustrating a schematic configuration of a part of a memory cell region of a semiconductor device according to an embodiment.

FIGS. 2A to 2C are diagrams illustrating a schematic configuration of a semiconductor device according to the embodiment. FIG. 2A is a layout plan view illustrating a schematic configuration of the memory cell region of the semiconductor device according to the embodiment, and is an enlarged view of the region P in FIG. 1. FIG. 2B is a vertical section illustrating a schematic configuration of a portion along the line A-A in FIG. 2A. FIG. 2C is a vertical section illustrating a schematic configuration of a portion along the line B-B in FIG. 2A.

FIG. 3 is a circuit diagram illustrating a schematic configuration of an equivalent circuit of memory cells of the semiconductor device according to the embodiment.

FIGS. 4A to 4C, FIGS. 5A to 5C, FIGS. 6A to 6C, FIGS. 7A and 7B, FIGS. 8A to 8C, FIGS. 9A and 9B, FIGS. 10A and 10B, FIGS. 11A to 11C, and FIGS. 2A to 2C are diagrams sequentially illustrating a method of forming the semiconductor device according to the embodiment, and each illustrates an example of a schematic configuration in an exemplary process stage. FIGS. 2A to 2C are diagrams illustrating the schematic configuration in a step following the step illustrated in FIGS. 11A to 11C. FIGS. 4A, 5A, 6A, 7A, 8A, 9A, 10A, and 11A are plan views each illustrating a schematic configuration of the semiconductor device according to the embodiment. FIGS. 4B, 6B, 7B, 8B, 9B, and 11B are vertical sections illustrating the schematic configurations of the portions along the lines B-B in FIGS. 4A, 5A, 6A, 7A, 8A, 9A, and 11A, respectively. FIGS. 4C, 6C, 8C, and 11C are vertical sections illustrating the schematic configurations of the portions along the lines C-C in FIGS. 4A, 5A, 6A, 8A, and 11A, respectively.

### DETAILED DESCRIPTION

Various embodiments of the present disclosure will be explained below in detail with reference to the accompanying drawings. The following detailed description refers to the accompanying drawings that show, by way of illustration, specific aspects and various embodiments of the present disclosure. The detailed description provides sufficient detail to enable those skilled in the art to practice these embodiments of the present disclosure. Other embodiments may be utilized, and structure, logical and electrical changes may be made without departing from the scope of the present disclosure. The various embodiments disclosed herein are not necessary mutually exclusive, as some disclosed embodiments can be combined with one or more other disclosed embodiments to form new embodiments.

Hereinafter, a semiconductor device 1 and a method of forming the same according to the embodiment will be described with reference to the drawings. The semiconductor device 1 is described by taking DRAM as an example. In the description of the embodiment, common or related elements and elements that are substantially the same are denoted with the same signs, and the description thereof will be reduced or omitted. In the drawings, the dimensions and dimensional ratios of each portion in each of the drawings do not necessarily match the actual dimensions and dimensional rations in the embodiment. The vertical direction refers to the up and down direction in the case where the semiconductor substrate is on the downside, and the horizontal direction refers to the direction parallel to the surface of the semiconductor substrate.

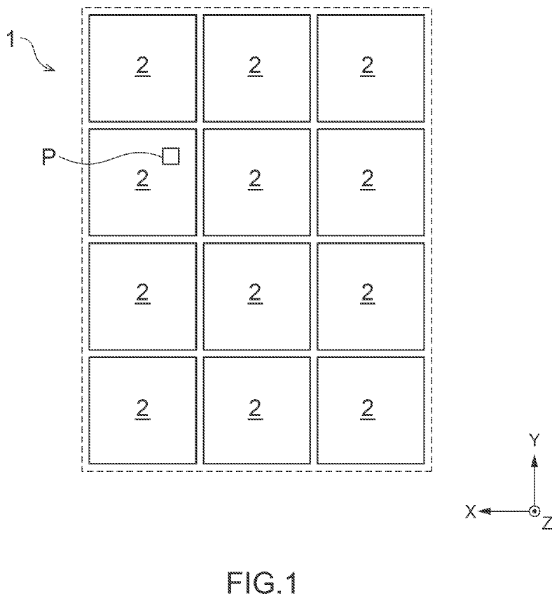

FIG. 1 is a layout plan view illustrating the schematic configuration of the semiconductor device 1 according to the embodiment. As illustrated in FIG. 1, the semiconductor device 1 comprises a plurality of memory mats 2 arranged in a matrix on a semiconductor substrate 30.

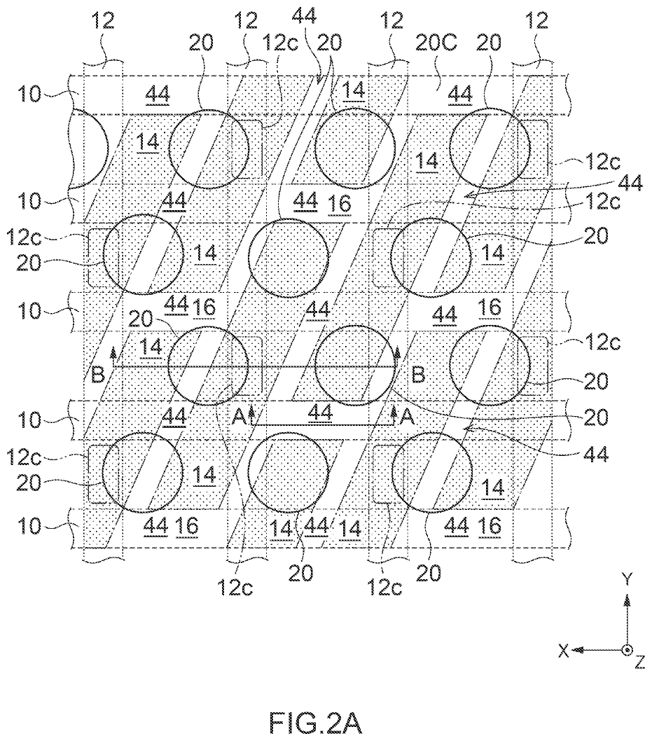

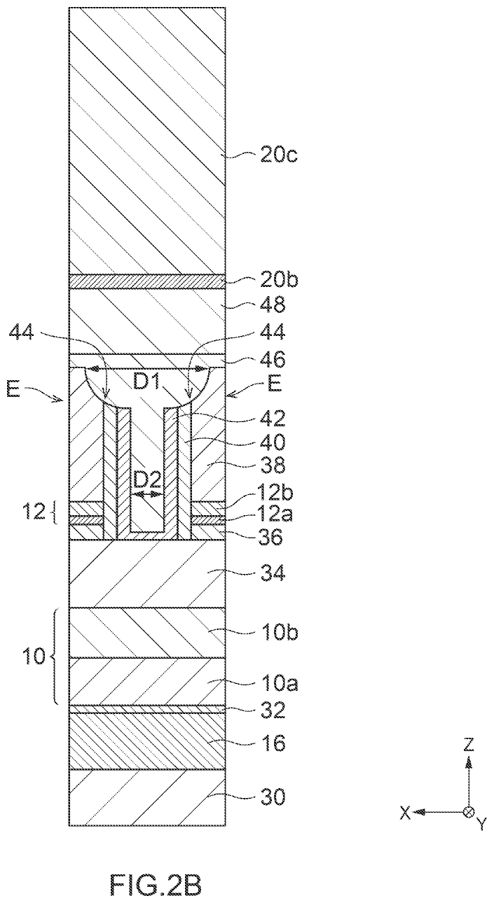

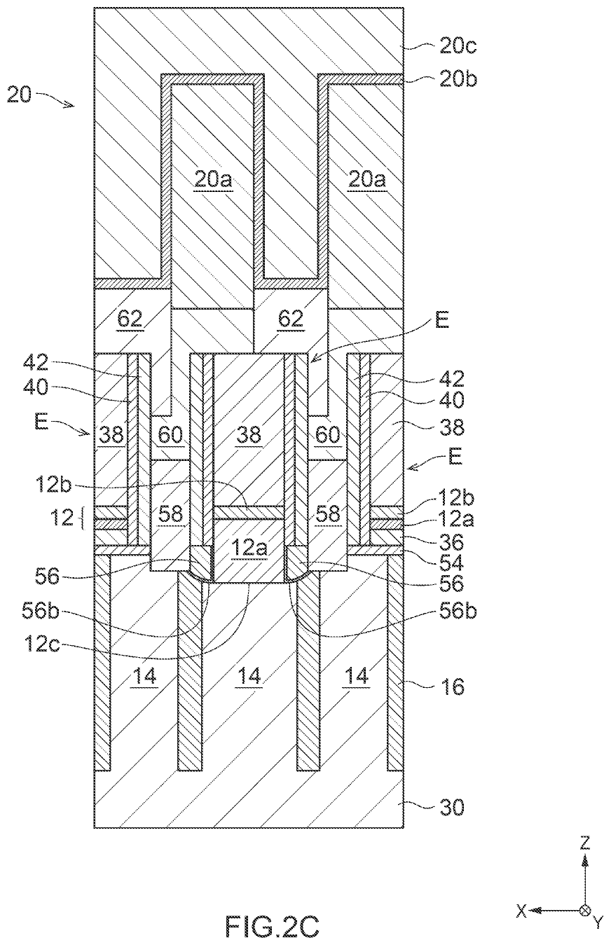

As illustrated in FIGS. 2A, 2B, and 2C, in each of the memory mats 2, a plurality of active regions 14 and an isolation 16 surrounding active regions 14 are formed on the semiconductor substrate 30. In the isolation 16, an insulating material is embedded into trenches formed in the semiconductor substrate 30. The isolation 16 has a function of electrically isolating adjacent active regions 14 from each other. The active regions 14 are demarcated by the isolation 16, and have island shapes extending in a prescribed direction.

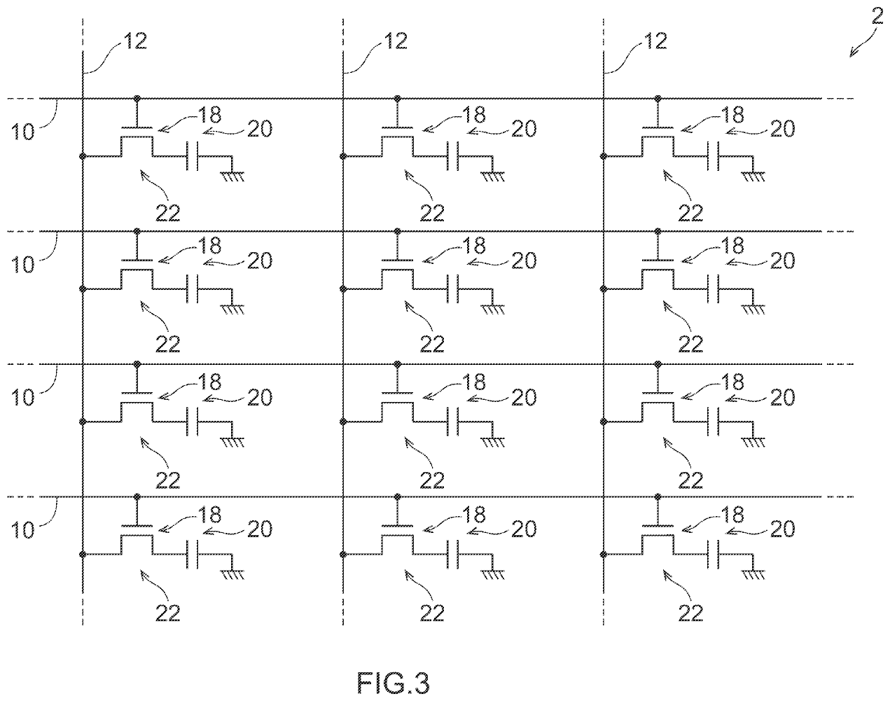

In the memory mats 2, a plurality of word lines 10, a plurality of bit lines 12 arranged to intersect the word lines 10, and a plurality of storage capacitors 20 are provided. The plurality of word lines 10 are arranged in parallel so as to elongate in the X direction of the drawings. The plurality of bit lines 12 are arranged in parallel so as to elongate in the Y direction of the drawings. The X direction and Y direction are substantially perpendicular. As illustrated in FIG. 3, a plurality of memory cells 22 are provided in the memory mats 2. Each of the plurality of memory cells 22 is provided at an intersection between a word line 10 and a bit line 12. Each memory cell 22 comprises a word line 10, a bit line 12, and a storage capacitor 20.

A bit contact 12c is provided in a central part of the active regions 14. The bit line 12 is connected to the active region 14 through the bit contact 12c. Adjacent word lines 10 among the plurality of word lines 10 are arranged to sandwich the bit contact 12c.

As illustrated in FIG. 2B, the isolation 16, a gate insulating film 32, and the word lines 10 are provided on the semiconductor substrate 30. FIG. 2B is a vertical section of the portion passing along the word lines 10 in the direction along the extension direction of the word lines 10. The word line 10 comprises a first word-conducting part 10a and a second word-conducting part 10b. The semiconductor substrate 30 comprises single-crystal silicon, for example. The isolation 16 comprises silicon dioxide (SiO₂), for example. The gate insulating film 32 comprises silicon dioxide (SiO₂), for example. The first word-conducting part 10a comprises titanium (Ti), for example, and the second word-conducting part 10b comprises polysilicon (poly-Si) doped with an impurity such as phosphorus (P), for example. The word line 10 functions as an access transistor 18 of the memory cell 22.

A first insulating film 34 is provided on the word line 10. The first insulating film 34 comprises silicon nitride (SiN), for example. A bit-line structure E is provided on the first insulating film 34. The bit-line structure E comprises a bit line 12, a second insulating film 36 provided below the bit line 12, and a third insulating film 38 provided above the bit line 12. The bit-line structure E also comprises a fourth insulating film 40 provided on side-walls of the second insulating film 36, the bit line 12, and the third insulating film 38, and a fifth insulating film 42 provided on a side-wall of the fourth insulating film 40. The second insulating film 36, the third insulating film 38, and the fifth insulating film 42 comprise silicon nitride (SiN). The fourth insulating film 40 is a low-k film comprising silicon oxide (SiO) or a silicon oxycarbide film (SiOC), for example. The bit-line structure E comprises a taper-shaped segment 44 and a protruding segment. The taper-shaped segment 44 is provided across the third insulating film 38, the fourth insulating film 40, and the fifth insulating film 42. Due to the taper-shaped segment 44, the width, in the X direction of the drawings, of the upper portion between adjacent bit-line structures E is widened. The distance D1, in the X direction, between the upper portions of adjacent bit-line structures E is greater than the distance D2, in the X direction, between the lower portions of adjacent bit-line structures E. The taper-shaped segments 44 are disposed on the word line 10. Between the taper-shaped segments 44 is a less taper-shaped segment that is not the taper-shaped segment 44. As illustrated in FIG. 2A, the taper-shaped segments 44 and the less taper-shaped segments appear alternately in the Y direction.

A sixth insulating film 46 is provided to be embedded between adjacent bit-line structures E. The sixth insulating film 46 covers the upper and side surfaces of the bit-line structures E. A seventh insulating film 48 is provided on top of the sixth insulating film 46. On top of the seventh insulating film 48, a capacitive insulating film 20b and a top electrode 20c included in the storage capacitor 20 described later are provided. Each of the sixth insulating film 46 and the seventh insulating film 48 comprises an insulating material such as silicon nitride (SiN), for example.

As above, the semiconductor device 1 according to the embodiment comprises the bit-line structures E which are provided on top of the word lines 10 and on the upper and side portions of the bit lines 12 in the direction along the extension direction of the word lines 10. The bit-line structures E comprise the taper-shaped segments 44 at the upper portion thereof The sixth insulating film 46 is provided between and at the upper portion of adjacent bit-line structures E. The sixth insulating film 46 is embedded between adjacent bit-line structures E and has no voids.

As illustrated in FIG. 2C, in the semiconductor device 1 according to the embodiment, the isolation 16 and the active regions 14 demarcated by the isolation 16 are provided on the semiconductor substrate 30. An eighth insulating film 54 is provided on top of the active region 14 and top of the isolation 16. The isolation 16 comprise an insulating material such as silicon dioxide (SiO₂), for example.

The semiconductor device 1 comprises the bit contact 12c that connects the bit line 12 with the active region 14. At the bit contact 12c, the bit line 12 and the active region 14 contact each other and are electrically connected. The storage capacitor 20 is provided above the bit-line structure E. The storage capacitor 20 comprises a bottom electrode 20a, a capacitive insulating film 20b, and a top electrode 20c. Each of the bottom electrode 20a and the top electrode 20c comprises a conductive material such as titanium nitride (TiN), for example. The capacitive insulating film 20b comprises a high-k insulating material such as zirconium oxide (ZrO₂) or hafnium oxide (HfO₂), for example.

The storage capacitor 20 is connected to the active region 14 through a first capacitive contact electrode 58 and a second capacitive contact electrode 60. The first capacitive contact electrode 58 and the second capacitive contact electrode 60 are arranged between adjacent bit-line structures E in the Y direction of the drawings. The first capacitive contact electrode 58 comprises a conductive material such as polysilicon (poly-Si) containing an impurity such as phosphorus (P), for example. The second capacitive contact electrode 60 comprises a conductive material such as titanium nitride (TiN), for example. The first capacitive contact electrode 58 and the second capacitive contact electrode 60 function, as a whole, as a capacitive contact electrode that connects the storage capacitor 20 to the active region 14.

Between the capacitive contact electrode and the bit line 12 adjacent thereto, the third insulating film 38, the fourth insulating film 40, and the fifth insulating film 42 are provided. At the bit contacts 12c, a bit contact insulating portion 56 and a liner insulating film 56b are additionally provided. The capacitive contact electrode and the bit lines 12 are insulated from each other by the third insulating film 38, the fourth insulating film 40, the fifth insulating film 42, the bit contact insulating portion 56, and the liner insulating film 56b. A ninth insulating film 62 is provided between adjacent pairs of the bottom electrodes 20a of storage capacitors 20 and the second capacitive contact electrodes 60. The pairs of the bottom electrodes 20a and the second capacitive contact electrodes 60 are insulated by the ninth insulating film 62 provided on top and partially on the side surfaces of the bit-line structures E. The ninth insulating film 62 comprises silicon nitride (SiN), for example.

FIG. 3 illustrates an equivalent circuit of a memory cell array of the memory mat 2 included in the semiconductor device 1. A plurality of memory cells 22 are arranged in a matrix, with each memory cell 22 being connected to an intersection point between the plurality of word lines 10 and the plurality of bit lines 12, each of which are disposed linearly. A single memory cell 22 includes a pair of an access transistor 18 and a storage capacitor 20. The access transistor 18 comprises a metal-oxide-semiconductor field-effect transistor (MOSFET). The word lines 10 function as the gate electrodes of the access transistors 18. One of the source or the drain of the access transistor 18 is connected to a bit line 12, while the other is connected to the storage capacitor 20. The storage capacitor 20 comprises a capacitor and stores data by holding accumulated charge.

When writing data to one of the memory cells 22, a potential that turns on the access transistor 18 is applied to the word line 10, while a low potential or a high potential corresponding to “0” or “1” of the data to be written is applied to the bit line 12. When reading out data from one of the memory cells 22, a potential that turns on the access transistor 18 is applied to the word line 10, and a data determination is made by having a sense amplifier connected to the bit line 12 sense the potential drawn from the storage capacitor 20 to the bit line 12.

Next, FIGS. 2A, 2B, and 2C to FIGS. 11A, 11B, and 11C will be referenced to describe a method of forming the semiconductor device 1 according to the embodiment. The method of forming the semiconductor device 1 will be described in sequential steps.

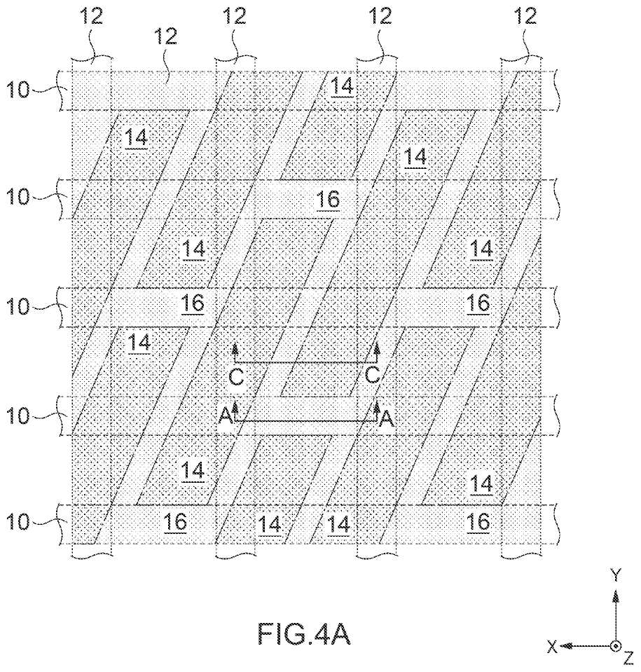

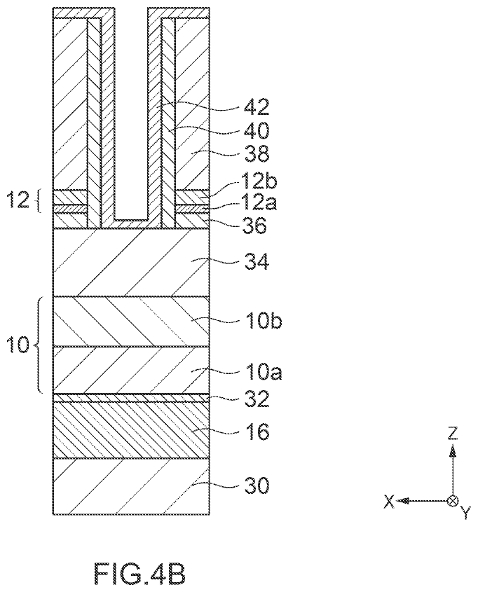

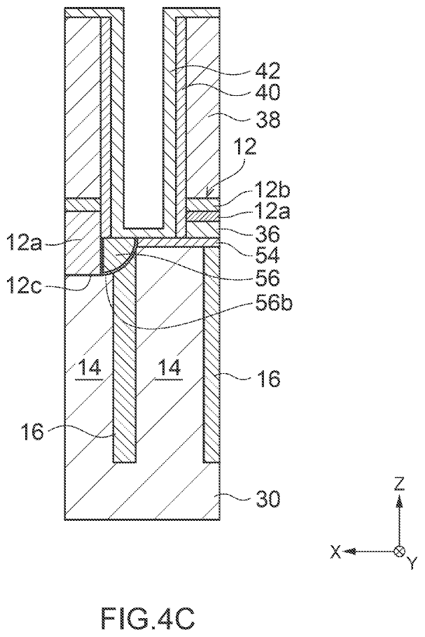

First, the steps until the structure illustrated in FIGS. 4A, 4B, and 4C is obtained will be described. As illustrated in FIGS. 4A, 4B, and 4C, the isolation 16 and the active regions 14 are formed on the semiconductor substrate 30. The isolation 16 is formed by using known lithography technology and anisotropic dry etching technology to form a trench to a prescribed depth in the semiconductor substrate 30 and embedding an insulating material such as silicon dioxide (SiO₂), for example. The insulating material formed in the isolation 16 is deposited using chemical vapor deposition (hereinafter referred to as CVD), for example. Next, the eighth insulating film 54 is formed over the entire surface. The eighth insulating film 54 comprises silicon dioxide (SiO₂), for example, and is formed by CVD, for example.

Next, trenches are formed in the regions where the word lines 10 are to be formed, and in the trench, the gate insulating film 32, the first word-conducting part 10a, the second word-conducting part 10b, and the first insulating film 34 are formed sequentially. When forming the trenches, the eighth insulating film 54 is removed. The gate insulating film 32 comprises silicon oxynitride (SiON), for example. The gate insulating film 32 is formed by thermal oxynitridation of the semiconductor substrate 30, for example. The first word-conducting part 10a comprises titanium (Ti), for example, and the second word-conducting part 10b comprises polysilicon (poly-Si) doped with an impurity such as phosphorus (P), for example.

The first word-conducting part 10a, the second word-conducting part 10b, and the first insulating film 34 are formed inside the trenches by repeatedly depositing respective films and etching back using anisotropic dry etching technology. The first word-conducting part 10a is deposited by CVD, for example, and then is etched back using anisotropic dry etching technology. The second word-conducting part 10b is deposited using CVD, for example, while introducing an impurity such as phosphorus (P) during the deposition, for example. Thereafter, etchback is performed using anisotropic dry etching technology. The first insulating film 34 comprises silicon nitride (SiN), for example. The first insulating film 34 is deposited by CVD, for example. Thereafter, etchback is performed using anisotropic dry etching technology.

As illustrated in FIG. 4A, the word lines 10 are patterned so as to elongate in the X direction and be arranged in parallel with a prescribed spacing in the Y direction. The first insulating film 34 is formed on top of the word line 10 and in the same shape as the word line 10. At this time, the word lines 10 are not formed in the region illustrated in FIG. 4C.

Thereafter, the second insulating film 36 is formed on top of the first insulating film 34 and on top of the eighth insulating film 54. The second insulating film 36 comprises an insulating material such as silicon nitride (SiN), for example. Next, as illustrated in FIG. 4C, known lithography technology and anisotropic dry etching technology are used to etch a portion of the second insulating film 36, the semiconductor substrate 30, and the isolation 16 in the region where the bit contact 12c is to be formed. With this process, the bit contact 12c is formed.

Next, a first bit-conducting part 12a, a second bit-conducting part 12b, and the third insulating film 38 are deposited. The first bit-conducting part 12a comprises a conductive material such as polysilicon (poly-Si) doped with an impurity such as phosphorus (P), for example. The second bit-conducting part 12b comprises a conductive material such as titanium nitride (TiN), for example. The third insulating film 38 comprises an insulating material such as silicon nitride (SiN), for example. The first bit-conducting part 12a, the second bit-conducting part 12b, and the third insulating film 38 are deposited by CVD, for example.

On the side surface of the first bit-conducting part 12a at the bit contacts 12c, the liner insulating film 56b and the bit contact insulating portion 56 are formed. The liner insulating film 56b comprises silicon oxide, for example, and is formed by CVD, for example. The bit contact insulating portion 56 comprises silicon nitride, for example, and is formed by CVD, for example.

Thereafter, known lithography technology and anisotropic dry etching technology are used to sequentially etch the third insulating film 38, the second bit-conducting part 12b, the first bit-conducting part 12a, and the second insulating film 36 to form the bit lines 12. As illustrated in FIG. 4A, the bit lines 12 are patterned so as to elongate in the Y direction and be arranged in parallel with a prescribed spacing in the X direction. At this time, the first insulating film 34 is exposed in the region between the bit lines 12. The second insulating film 36 is formed under the bit line 12 and in the same shape as the bit line 12. The third insulating film 38 is formed on top of the bit line 12 and in the same shape as the bit line 12. At this time, the first insulating film 34 is exposed in the region between the bit lines 12.

Next, the fourth insulating film 40 is formed to cover the upper surface of the first insulating film 34, the side surfaces of the second insulating film 36, the first bit-conducting part 12a, the second bit-conducting part 12b, and the third insulating film 38, and upper surface of the third insulating film 38. The fourth insulating film 40 comprises an insulating material such as silicon dioxide (SiO₂) or a low-k film such as silicon oxycarbide (SiOC), for example. The fourth insulating film 40 is formed by CVD, for example. Next, the fourth insulating film 40 is etched back by anisotropic dry etching to remove the fourth insulating film 40 on top of the third insulating film 38 and top of the first insulating film 34. With this process, the fourth insulating film 40 is made to remain on the side surfaces of the second insulating film 36, the first bit-conducting part 12a, the second bit-conducting part 12b, and the third insulating film 38.

Next, the fifth insulating film 42 is formed to cover the top of the first insulating film 34, the side and upper surfaces of the fourth insulating film 40, and the upper surface of the third insulating film 38. The fifth insulating film 42 comprises silicon nitride, for example, and is formed by CVD, for example.

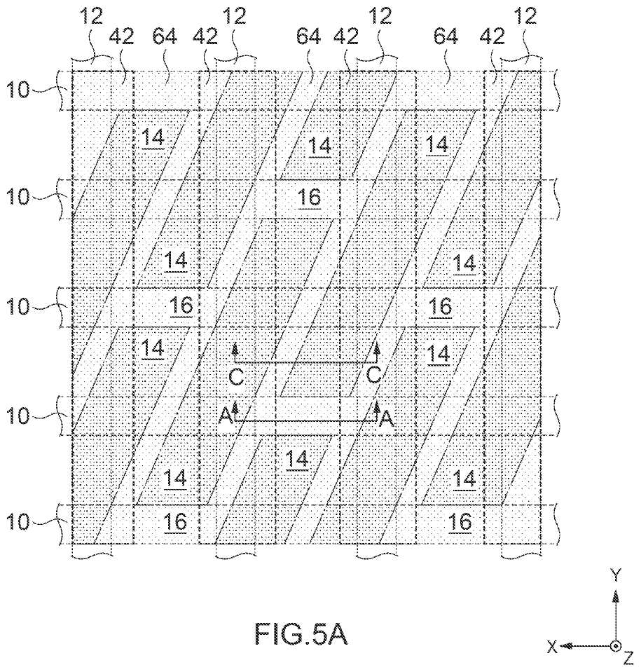

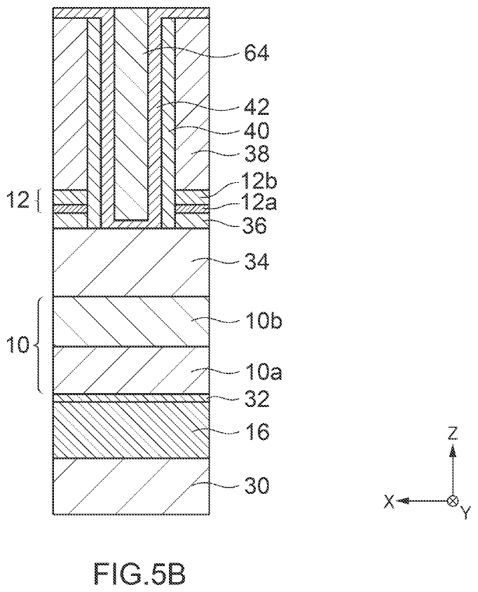

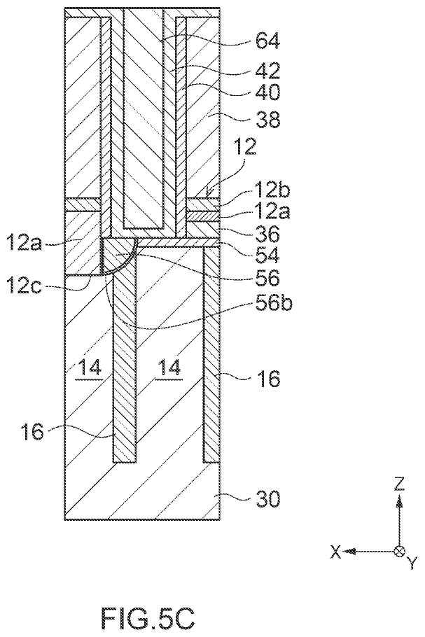

Next, as illustrated in FIGS. 5A, 5B, and 5C, a first sacrificial insulating film 64 is formed on top of the fifth insulating film 42. The first sacrificial insulating film 64 comprises a spin-on-glass (SOG) film, for example. For example, the first sacrificial insulating film 64 is formed by applying an SOG liquid containing a siloxane component, a solvent, and the others onto the semiconductor substrate 30 by spin coating, causing the solvent or the like to evaporate with a heat treatment, and curing the film. After that, by chemical mechanical polishing (hereinafter referred to as CMP) or etching back using anisotropic dry etching technology, for example, the first sacrificial insulating film 64 is removed until the upper surface of the fifth insulating film 42 is exposed.

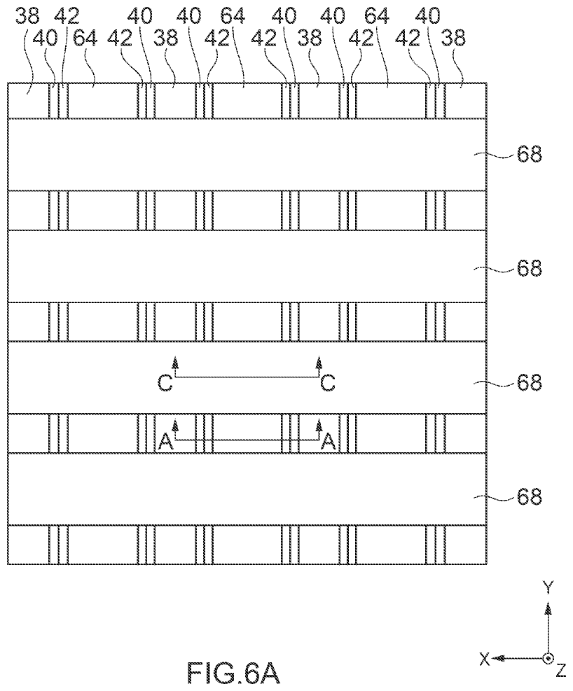

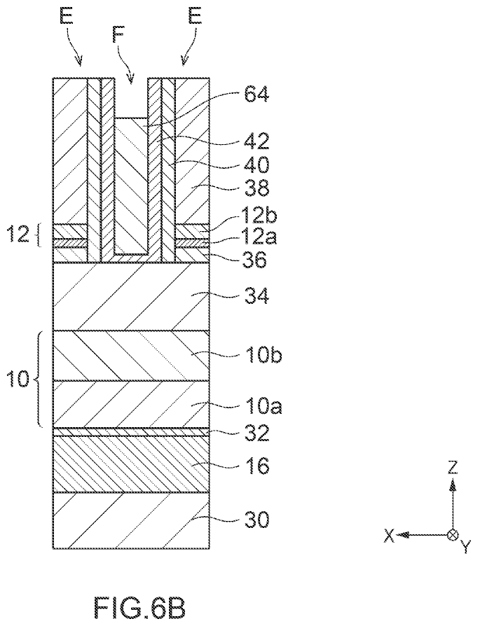

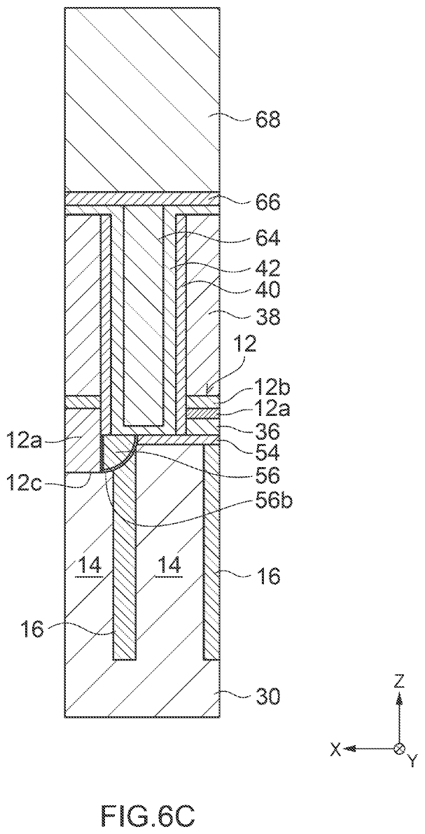

Next, as illustrated in FIGS. 6A, 6B, and 6C, a second sacrificial insulating film 66 and a hard mask 68 are formed to cover the upper surfaces of the fifth insulating film 42 and the first sacrificial insulating film 64. The second sacrificial insulating film 66 comprises an insulating material such as silicon dioxide (SiO₂), for example. The second sacrificial insulating film 66 is formed by CVD, for example. The hard mask 68 comprises carbon or polysilicon. The hard mask 68 is formed by CVD, for example, and is thereafter patterned by known lithography technology, for example. The region illustrated in FIG. 6B is a region in which a word line 10 is formed, and corresponds to an opening where the hard mask 68 is not formed.

Next, the hard mask 68 is used as an etching mask to remove the second sacrificial insulating film 66 and a portion of the first sacrificial insulating film 64 in the opening by etching. The second sacrificial insulating film 66 is etched under etching conditions such that silicon nitride and silicon dioxide have substantially the same etching rate, for example. At this time, the upper portions of the third insulating film 38, the fourth insulating film 40, and the fifth insulating film 42 are also etched simultaneously. With this process, the bit-line structures E that cover the upper and side-surface portions of the bit lines 12 are formed. Next, the upper portion of the first sacrificial insulating film 64 is partially removed by an etching. This etching is performed under conditions such that the etching rate of the bit-line structures E is lower than the etching rate of the first sacrificial insulating film 64. Consequently, little or no etching of the bit-line structures E occurs, and only the upper portion of the first sacrificial insulating film 64 is etched. Through this etching, a recess F is formed in the upper portion of the first sacrificial insulating film 64.

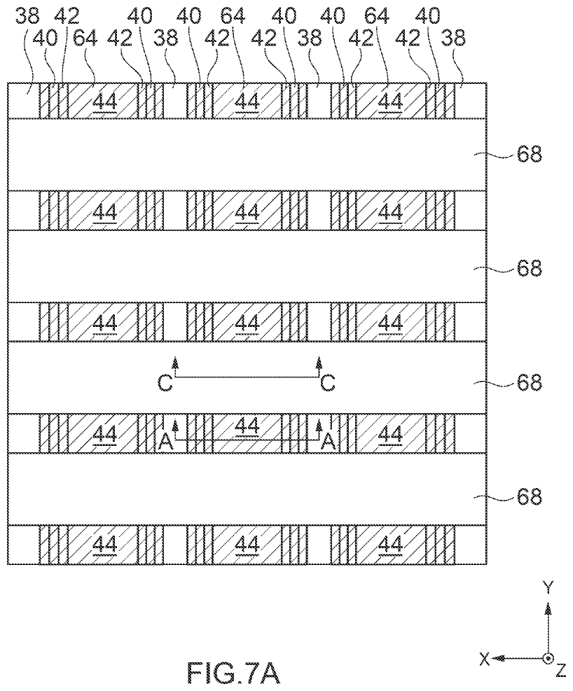

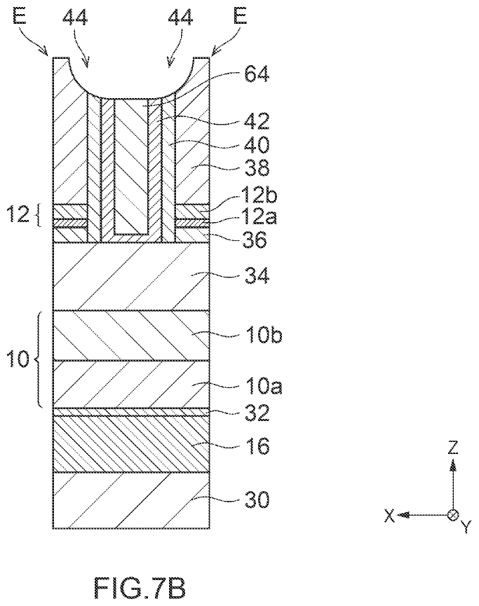

Next, as illustrated in FIGS. 7A and 7B, the hard mask 68 is used as an etching mask to perform isotropic dry etching on the bit-line structures E. This etching is performed under conditions such that the etching rate of the bit-line structures E is higher than the etching rate of the first sacrificial insulating film 64. Through this etching, the upper portion of the bit-line structure E is etched isotropically, and the taper-shaped segments 44 and protruding segment are formed. Note that in this step, the region of the portion along the line C-C in FIG. 7A is covered by the hard mask 68, and consequently is not changed by the etching. For this reason, the vertical section of the portion along the line C-C in FIG. 7A is the same as FIG. 6C.

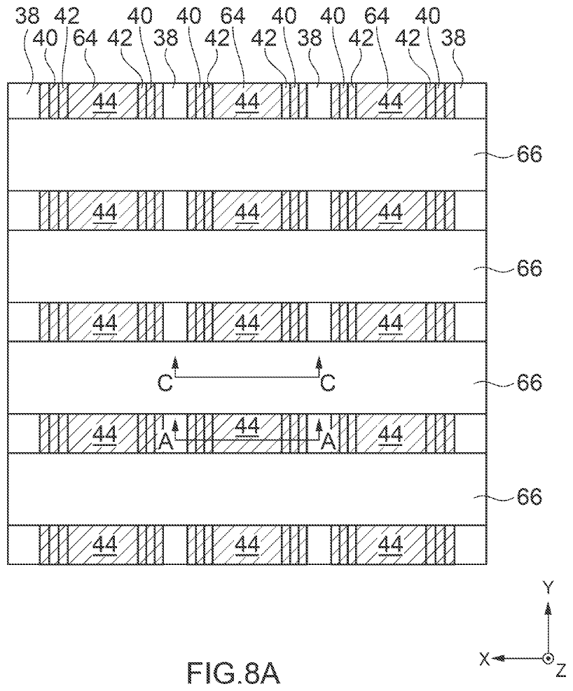

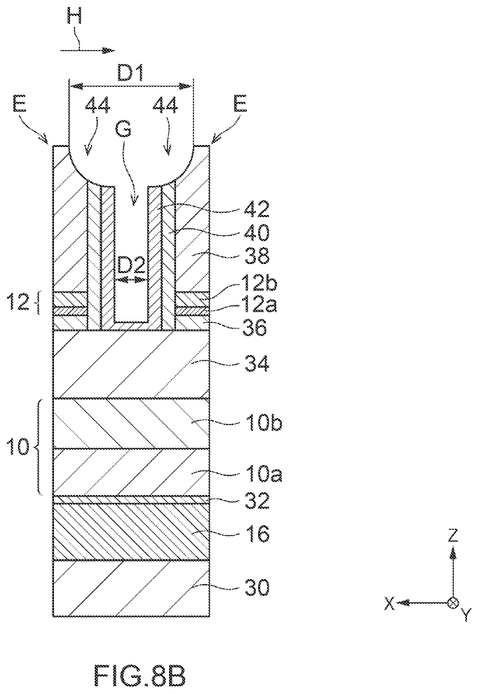

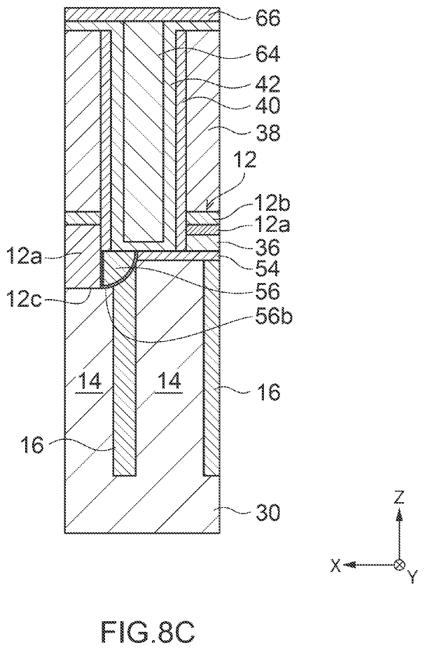

Next, as illustrated in FIGS. 8A, 8B, and 8C, the first sacrificial insulating film 64 is removed using known dry etching technology. This etching is performed under conditions such that the etching rate of the first sacrificial insulating film 64 is higher than the etching rate of the bit-line structures E. Through this etching, the first sacrificial insulating film 64 is selectively removed. A gap G is formed between the bit-line structures E. Since the taper-shaped segments 44 are formed in the upper portions of the bit-line structures E, the gap between the upper portions of adjacent bit-line structures E widens. The distance D1, in the X direction, between the upper portions of adjacent bit-line structures E is greater than the distance D2, in the X direction, between the lower portions of adjacent bit-line structures E. After that, the hard mask 68 is removed. The hard mask 68 is removed by oxygen ashing, for example.

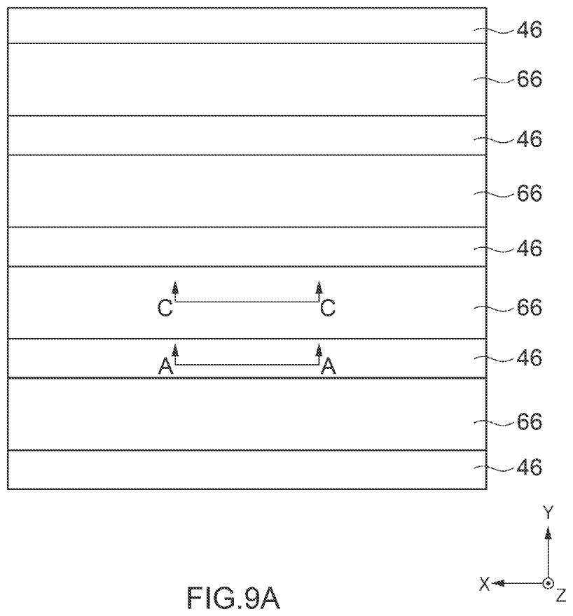

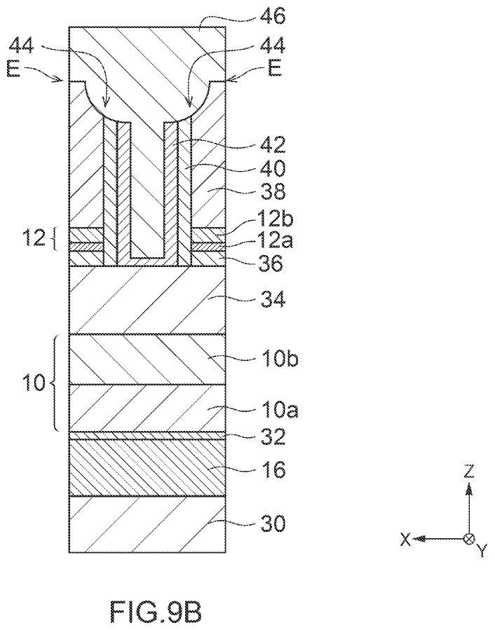

Next, as illustrated in FIGS. 9A and 9B, the sixth insulating film 46 is formed to make the upper portion of the bit-line structures E and the gap G between adjacent bit-line structures E be embedded, and cover the second sacrificial insulating film 66. The sixth insulating film 46 comprises an insulating material such as silicon nitride (SiN), for example. The sixth insulating film 46 is formed by CVD, for example.

At this time, for example, thermal stress due to heat treatment, stress due to the deposited films, or the like may cause the bit-line structure E on the left side in FIG. 8B, for example, to be distorted in the direction of the arrow H illustrated in FIG. 8B, in some cases. If this occurs, the width of the gap G will be narrowed at the upper portions of the bit-line structures E. For example, if the bit-line structures E is distorted by the heat treatment in the step illustrated in FIGS. 5A, 5B, and 5C, a portion of the first sacrificial insulating film 64 may remain inside the gap G when the first sacrificial insulating film 64 is etched, in some cases. In such cases, if wet etching using buffered hydrofluoric acid (hereinafter referred to as BHF) is performed in a later step, for example, the first sacrificial insulating film 64 may be selectively removed and a void may be formed, in some cases. Moreover, when depositing the sixth insulating film 46, the interior of the gap G may not be completely filled by the sixth insulating film 46 and a void may be formed, in some cases. If the void is formed inside the gap G, a conductive material may be formed inside the void in a later step, for example, and in some cases, adjacent bit lines 12 or adjacent capacitive contacts may be short-circuited, for example. In the embodiment, the taper-shaped segments 44 are provided in the upper portions of the bit-line structures E, thereby suppressing a narrowing of the width of the gap G at the upper portions of the bit-line structures E. With this configuration, the formation of a void inside the gap G is suppressed.

Next, the sixth insulating film 46 is etched back by anisotropic dry etching to reduce the thickness of the sixth insulating film 46. The etchback is performed until the surface of the second sacrificial insulating film 66 is exposed. In this step, the thickness of the sixth insulating film 46 may be reduced using CMP instead of anisotropic dry etching. The vertical section of the portion along the line C-C in FIG. 9A is the same as FIG. 8C.

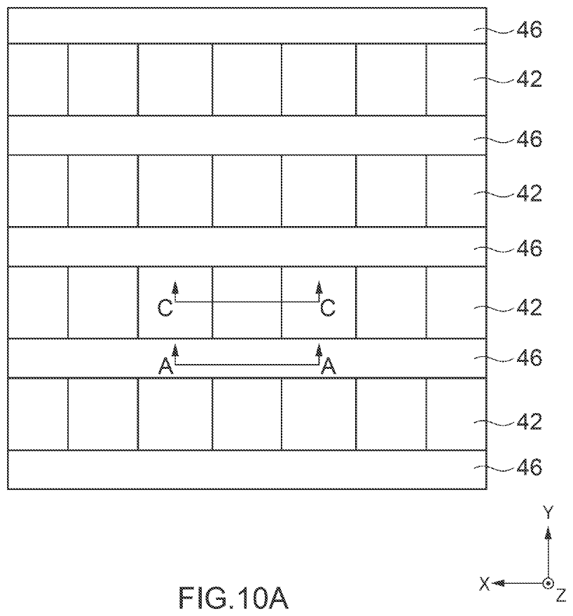

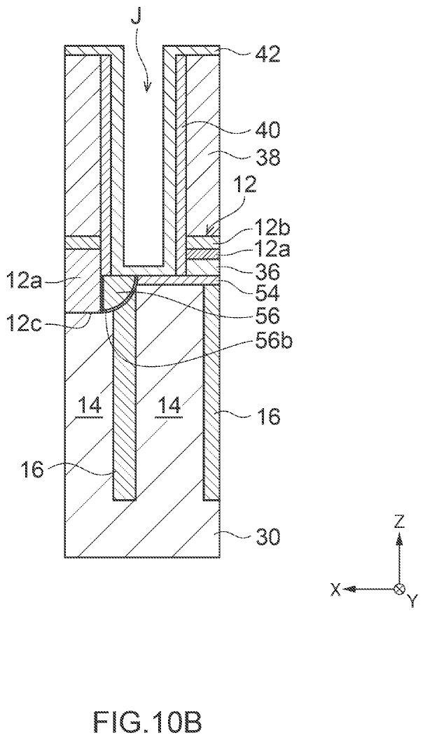

Next, as illustrated in FIGS. 10A and 10B, the second sacrificial insulating film 66 and the first sacrificial insulating film 64 are removed using BHF, for example. In etching by BHF, little or no etching of silicon nitride occurs, and therefore the second sacrificial insulating film 66 and the first sacrificial insulating film 64 are selectively removed, and a gap J is formed. In this step, the vertical section of the portion along the line A-A in FIG. 10A is the same as FIG. 9B. This region is covered by the sixth insulating film 46 comprising silicon nitride, and consequently is not etched by BHF.

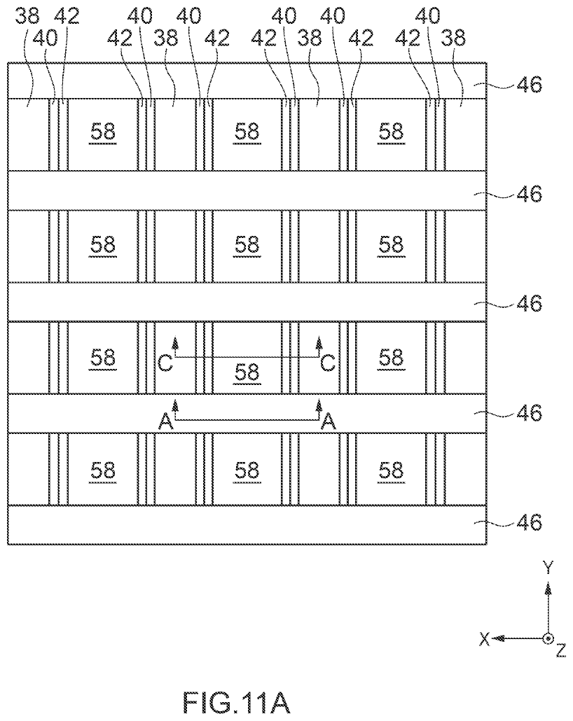

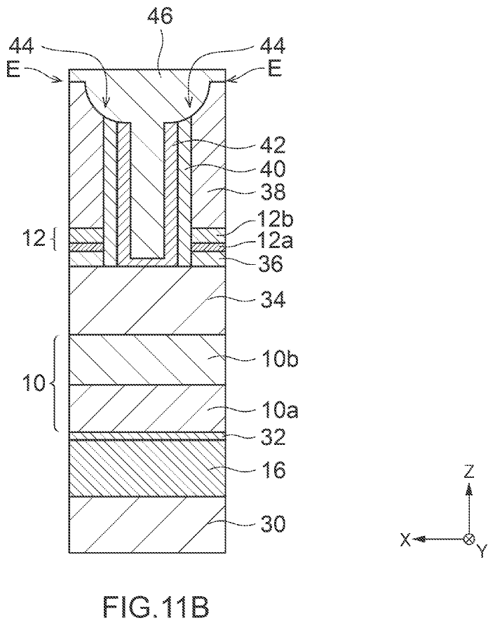

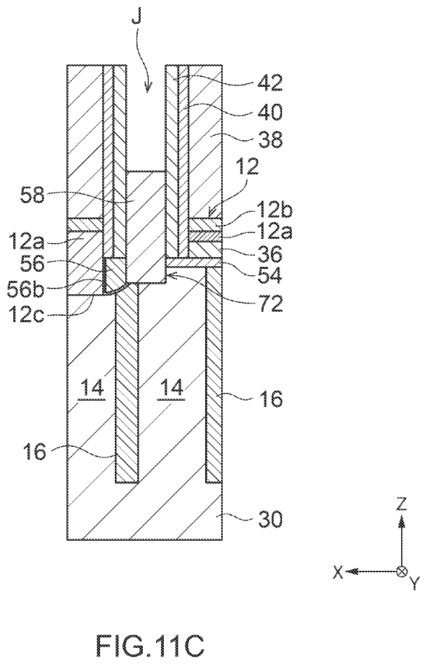

Next, as illustrated in FIGS. 11A, 11B, and 11C, anisotropic dry etching is performed under conditions such that silicon dioxide, silicon nitride, and silicon have substantially the same etching rate. As illustrated in FIG. 11B, the portion above the word lines 10 is covered by the sixth insulating film 46. For this reason, the bit lines 12 and word lines 10 below the sixth insulating film 46 are not etched. Through this etching, the thickness of the sixth insulating film 46 is reduced.

Also, in the region illustrated in FIG. 11C, the third insulating film 38, the fourth insulating film 40, and the fifth insulating film 42 exist above and on the side-wall of the bit line 12, and therefore the bit line 12 is not etched. This dry etching reduces the thickness, in the Z direction, of the fifth insulating film 42, the third insulating film 38, and the fourth insulating film 40 above the bit line 12.

In the region illustrated in FIG. 11C, the fifth insulating film 42, the eighth insulating film 54, the bit contact insulating portion 56, the liner insulating film 56b, the active region 14, and the isolation 16 at the bottom of the gap J are etched in the Z direction. Through this etching, etching progresses at the bottom of the gap J, and the active region 14 is exposed.

Next, polysilicon (poly-Si) containing phosphorus (P), for example, is deposited to fill the gap J and cover the third insulating film 38, the fourth insulating film 40, and the fifth insulating film 42. Polysilicon is deposited using CVD while introducing phosphorus, for example. Next, the polysilicon is etched back by anisotropic dry etching such that the polysilicon only remains in the lower portion of the gap J, thereby forming the first capacitive contact electrode 58. The first capacitive contact electrode 58 contacts the active region 14 in the lower portion and is electrically connected to the active region 14. According to the above, the structure illustrated in FIGS. 11A, 11B, and 11C is formed.

Next, as illustrated in FIGS. 2A, 2B, and 2C, the seventh insulating film 48 is formed in the region illustrated in FIG. 2B. The seventh insulating film 48 is formed by CVD, for example. In the region illustrated in FIG. 2C, after the second capacitive contact electrode 60 connected to the first capacitive contact electrode 58 and the bottom electrode 20a are formed, the ninth insulating film 62, the capacitive insulating film 20b, and the top electrode 20c are formed. The capacitive insulating film 20b and the top electrode 20c are also formed in the region illustrated in FIG. 2B.

The second capacitive contact electrode 60 and the bottom electrode 20a are formed by, for example, forming and then patterning titanium nitride using known lithography technology and anisotropic dry etching technology. The ninth insulating film 62 is formed by, for example, depositing and then etching back silicon nitride by anisotropic dry etching. The capacitive insulating film 20b and the top electrode 20c are formed by CVD, for example.

According to the above steps, the semiconductor device 1 according to the embodiment is formed.

According to the semiconductor device 1 and the method for forming the same according to the embodiment, the following effects are achieved.

In the semiconductor device 1, the taper-shaped segments 44 are provided in the upper portions of the bit-line structures E, and therefore voids are not formed in the sixth insulating film 46 embedded in the gap G between adjacent bit-line structures E. With this arrangement, the occurrence of a short circuit between adjacent memory cells 22 is suppressed, for example.

As above, DRAM is described as an example of the semiconductor device according to the embodiment, but the above description is merely one example and not intended to be limited to DRAM. Memory devices other than DRAM, such as static random access memory (SRAM), flash memory, erasable programmable read only memory (EPROM), magnetoresistive random access memory (MRAM), and phase-change memory, for example, are also applicable as the semiconductor device. Furthermore, devices other than memory, including a microprocessor and logic ICs such as an application specific integrated circuit (ASIC), for example, are also applicable as the semiconductor device according to the above embodiment. Furthermore, functional devices such as micro electro mechanical systems (MEMS) are also applicable as the semiconductor device according to the above embodiment.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a plurality of bit-line structures elongating in parallel in a first direction, each of the plurality of bit-line structures having a conductive portion and an insulating portion on the conductive portion;
wherein the insulating portion of each of the plurality of bit-line structures includes taper-shaped segments and less taper-shaped segments, which appear alternately along the first direction.

2. The apparatus of claim 1, further comprising a plurality of word lines elongating in parallel in a second direction substantially perpendicular to the first direction under the plurality of bit lines;
wherein the taper-shaped segments are above the plurality of word lines, respectively; and
wherein the less taper-shaped segments are not above the plurality of word lines, respectively.

3. The apparatus of claim 1, wherein the insulating portion of each of the plurality of bit-line structures includes the taper-shaped segments at a lower portion thereof and a protruding segment at an upper portion thereof.

4. The apparatus of claim 1, wherein, in the second direction, a distance between the upper portions of the taper-shaped segments of the adjacent bit-line structures is greater than a distance between the lower portions thereof.

5. The apparatus of claim 1, further comprising a side-wall insulating portion on side surfaces of both of the conductive portion and an insulating portion.

6. The apparatus of claim 1, wherein each of the conductive portions includes a multilayer of silicon and titanium nitride.

7. The apparatus of claim 1, wherein each of the insulating portions comprises silicon nitride.

8. The apparatus of claim 1, wherein each of the side-wall insulating portions comprises a multilayer of silicon nitride and silicon dioxide.

9. An apparatus comprising:
a plurality of bit lines elongating in parallel in a first direction; and
a plurality of multilayer structures, each of the multilayer structures comprising one of the bit lines and a first insulating film covering the top and side surfaces of each of the bit lines;
wherein each of the multilayer structures comprises a taper-shaped segment on an upper portion thereof, and a distance between upper portions of adjacent multilayer structures is greater than a distance between lower portions thereof.

10. The apparatus of claim 9, further comprising a plurality of word lines elongating in parallel in a second direction substantially perpendicular to the first direction under the plurality of bit lines;
wherein the taper-shaped segments are above the plurality of word lines, respectively; and
wherein the less taper-shaped segments are not above the plurality of word lines, respectively.

11. The apparatus of claim 9, further comprising second insulating films, each of the second insulating films filling a space between the adjacent multilayer structures.

12. The apparatus of claim 11, wherein each of the second insulating films includes substantially no void.

13. The apparatus of claim 9, wherein the first insulating film comprises silicon nitride.

14. The apparatus of claim 9, wherein the first insulating film comprises SiOC.

15. The apparatus of claim 11, wherein the second insulating film comprises silicon nitride.

16. A method comprising:
forming a plurality of first wirings elongating in parallel in a first direction on a substrate;
forming a conductive film and a first insulating film in order above the first wirings and the substrate;
etching the conductive film and the first insulating film with a mask to form a plurality of first multilayer structures including the conductive film and the first insulating film and elongating in parallel in a second direction different from the first direction;
forming a second insulating film and a third insulating film on each side surface of the first multilayer structures to form a plurality of second multilayer structures, each of the second multilayer structures including the first multilayer structure, the second insulating films and the third insulating film;
forming a fourth insulating film between the adjacent second multilayer structures;
etching back the fourth insulating film to expose the upper surface and the upper side surface of the second multilayer structure; and
isotropic etching on the first insulating film, the second insulating film, and the third insulating film to form a taper-shaped segment on an upper portion of the second multilayer structure.

17. The method of claim 16, wherein the conductive film acts as a second wiring.

18. The method of claim 16, wherein the second insulating film is formed by depositing an insulating film by CVD and etching back by anisotropic dry etching.

19. The method of claim 16, wherein the isotropic etching is performed under a condition that the etching rates of the first insulating film, the second insulating film and the third insulating film are substantially the same and using an etching mask provided above other than the first wiring.

20. The method of claim 16, wherein the first insulating film and the third insulating film comprise silicon nitride, and the second insulating film comprises SiOC.
